(19) United States
(12) Patent Application Publication
(10) Pub. No.: US 2004/0086132 A1
(43) Pub. Date: May 6, 2004

(54) Audio apparatus

(75) Inventors: Yasuhisa Abe, Yamagata-ken (JP); Hiroyuki Hamada, Saitama-ken (JP); Shintaro Hosoi, Saitama-ken (JP)

Correspondence Address: ARENT FOX KINTNER PLOTKIN & KAHN, PLLC, Suite 600, 1050 Connecticut Avenue, Washington, DC, 20036-5339, US

(73) Assignees: Pioneer Corporation; Tohoku Pioneer Corporation

(21) Appl. No.: 10/694,023

(22) Filed: Oct. 28, 2003

(30) Foreign Application Priority Data
Oct. 29, 2002 (JP) 2002-314304

(51) Int. Cl. H03G 3/00

(52) U.S. Cl. 381/61; 381/63

(57) ABSTRACT

An audio apparatus has a main speaker SPA receiving an audio signal from a sound source 10 and outputting sound of the sound source; sound effect audio signal processing circuits 12B, 12C, etc. for performing signal processing on the audio signal from the sound source 10 to generate a sound effect audio signal for reproduction of a sound effect required of the sound of the sound source; and sound effect speakers SPB, SPC, etc. each receiving the sound effect audio signal and outputting the sound effect required of the sound of the sound source.

### BACKGROUND OF THE INVENTION

1. Field of the Invention

This invention relates to an audio apparatus having an acoustic effect-producing function.

The present application claims priority from Japanese Application No. 2002-314304, the disclosure of which is incorporated herein by reference.

2. Description of the Related Art

Some conventionally known audio apparatuses have an acoustic effect-producing function of generating pseudo-sound of a reverberant sound and the like created in a concert hall from a music source such as a CD so as to produce, in a room at home or the like, a sound field similar to the original sound field in the concert hall, when music is reproduced.

FIG. 1 is a schematic block diagram illustrating the structure of a conventional audio apparatus having such an acoustic effect-producing function, in which an amplifier is omitted.

The conventional audio apparatus mixes a source sound signal a which is read out from a sound source 1 such as a CD or a music record, and a pseudo-acoustic sound (reverberation component-generating sound) signal b generated by means of extraction of a reverberation component from the source sound signal a for signal processing in an audio signal processing circuit 2, and then outputs the mixture to a speaker SP.

Then the pseudo-acoustic sound together with the sound of the sound source (hereinafter referred to as “source sound”) is outputted from the speaker SP in order to produce a sound field including reverberant sound and the like in a sound-reproduction space SF resembling the original sound field created in the concert hall.

However, in the structure of the conventional audio apparatus as described above, the source sound and the pseudo-acoustic sound are outputted into the single sound-reproduction space SF. Hence, the pseudo-acoustic sound is also affected by the so-called “acoustics” of the sound-reproduction space SF. As a result, a relation between the source sound and the pseudo-acoustic sound is repeated in each small portion of an indirect sound component in the sound-reproduction space SF.

The interrelationship between acoustic sound and direct sound in the concert hall or the like is originally weak, but the conventional audio apparatus is under a large influence of characteristics of the sound-reproduction space, and therefore the interrelationship between the source sound and the pseudo-acoustic sound is increased. Hence the conventional audio apparatus has the problem of making it difficult for a listener(s) to perceive acoustic sound in itself.

Further, when the conventional audio apparatus as described above is placed in a narrow space (e.g. a passenger chamber in a vehicle) for sound reproduction, there is produced the problem of an impossibility of satisfying all requirements for sound relating to the balance in tone quality, the localization, and the perception of sound field.

FIG. 2A shows the impulse response measured when speakers of the conventional audio apparatus are mounted on A-pillars in the passenger chamber of a vehicle. FIG. 2B shows the sound-pressure frequency characteristics obtained from analysis of the impulse response in FIG. 2A for a duration of 70 ms after it commences.

In FIG. 2A, the impulse response shows a waveform varying with the passage of time at a high level because of degeneracy resulting from sound reflection. In FIG. 2B, peaks and dips occur from a midpoint of a band toward the right. It is understood from the properties as described in FIGS. 2A and 2B that some of the conventional audio apparatuses have the problem of being incapable of providing smooth sound.

FIG. 3A shows the impulse response measured when speakers of the conventional audio apparatus are placed in a lower portion of a console in the passenger chamber of a vehicle. FIG. 3B shows the sound-pressure frequency characteristics obtained from analysis of the impulse response in FIG. 3A for a duration of 70 ms after it commences.

A spike waveform of the impulse response in FIG. 3A is less than that as shown in FIG. 2A, and the waves of characteristics in FIG. 3B are fewer. However, the wave form in the beginning portion of the impulse response in FIG. 3A, namely, the waveform of the direct sound, is smaller than that of the other portions subsequent to that. For this reason, it is understood that some of the conventional audio apparatuses have the problem of lack of stereo sound and ambience because of unclear sound localization.

### SUMMARY OF THE INVENTION

It is an object of the present invention to provide an audio apparatus improved by solving the problems associated with the conventional audio apparatuses as described above.

To attain the above object, an audio apparatus according to the present invention has a feature of including a main speaker receiving an audio signal from a sound source and outputting sound of the sound source; a signal processing circuit for performing signal processing on the audio signal sent from the sound source for generation of a sound effect required of the sound of the sound source; and at least one sound effect speaker receiving a sound effect audio signal generated by the signal processing circuit and outputting the sound effect required of the sound of the sound source.

The audio apparatus reads an audio signal from the sound source such as a CD, then performs the required signal processing on the audio signal for reproduction of the source sound, and then inputs the resulting audio signal to the main speaker. Thus, the source sound is outputted from the main speaker toward the inside of a sound-reproduction space served by the main speaker.

Further, the audio signal read from the sound source is also inputted to the signal processing circuit. Then, the signal processing circuit performs the signal processing on the audio signal to produce an audio signal for reproducing sound providing the acoustic effect required of the source sound outputted from the main speaker.

Then, the audio signal for reproducing the sound effect after completion of the signal processing in the signal processing circuit is inputted to at least one sound effect speaker. Thus, the sound effect is outputted from the sound effect speaker into the sound-reproduction space served by the sound effect speaker concerned.

As described above, according to the present invention, the audio apparatus includes a main speaker for outputting a source sound and a sound effect speaker for outputting a sound effect. The source sound is outputted from the main speaker toward the inside of the sound-reproduction space served by the main speaker concerned. The sound effect reproduced from the sound effect audio signal subjected to the signal processing by the signal processing circuit is outputted from the sound effect speaker toward the inside of the sound-reproduction space served by the sound effect speaker concerned.

Hence, as compared with the conventional audio apparatuses in which a source sound and a sound effect (pseudo-acoustic sound) are outputted together into a single sound-reproduction space, the audio apparatus according to the present invention is decreased in the degree of interrelationship between the source sound and the sound effect. As a result, the sound effect outputted from the sound effect speaker makes it possible for a listener(s) to listen to sound analogous to the original acoustic sound in the concert hall or the like.

With the audio apparatus, precise localization of the sound reproduced is provided. For example, when the audio apparatus is used as a vehicle-mounted audio apparatus, a listener(s) such as the driver of the vehicle is able to hear sound with balanced tone quality.

These and other objects and features of the present invention will become more apparent from the following detailed description with reference to the accompanying drawings.

### BRIEF DESCRIPTION OF THE DRAWINGS

FIG. 1 is a block diagram illustrating a conventional audio apparatus.

FIG. 2A is a graph showing impulse response resulting at output from a speaker of a conventional audio apparatus mounted on an A-pillar of a vehicle.

FIG. 2B is a graph showing sound pressure frequency characteristics of the speaker in FIG. 2A.

FIG. 3Ais a graph showing impulse response resulting at output from a speaker of a conventional audio apparatus mounted on a lower portion of a console of a vehicle.

FIG. 3B is a graph showing sound pressure frequency characteristics of the speaker in FIG. 3A.

FIG. 4 is a block diagram illustrating a first embodiment of the structure of an audio apparatus according to the present invention.

FIG. 5 is a block diagram illustrating the structure of a signal processing circuit of the audio apparatus.

FIG. 6 is a block diagram illustrating another example of the structure of the signal processing circuit of the audio apparatus.

FIG. 7A is a graph showing impulse response resulting at output from a main speaker of the audio apparatus.

FIG. 7B is a graph showing impulse response resulting at output from a sound effect speaker of the audio apparatus.

FIG. 8A is a graph showing impulse response obtained when the audio apparatus according to the present invention is used as a vehicle-mounted audio apparatus.

FIG. 8B is a graph showing sound pressure frequency characteristics of the audio apparatus in FIG. 8A.

FIG. 9 is a block diagram illustrating a second embodiment of the structure of the audio apparatus according to the present invention.

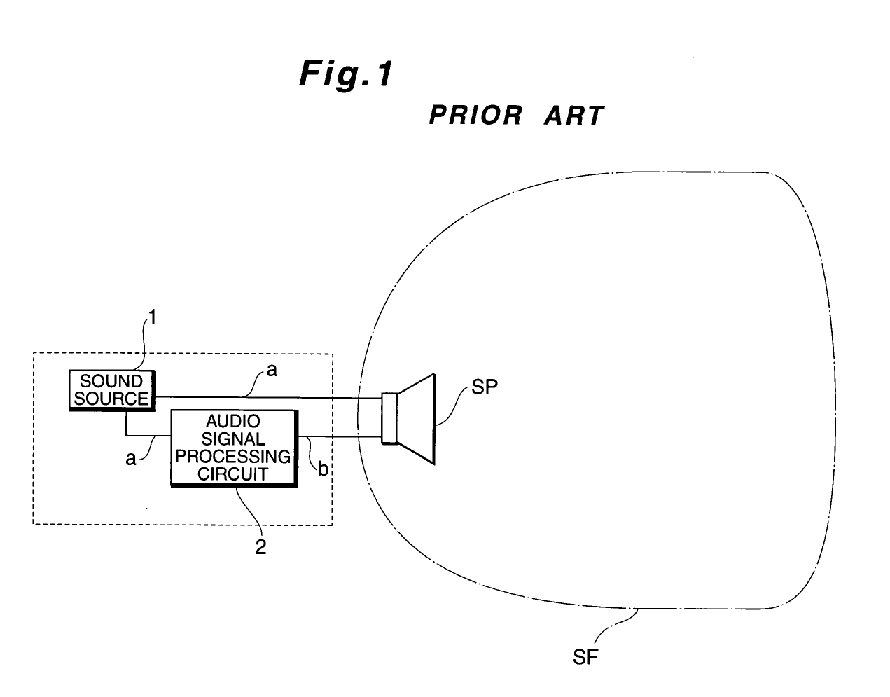

### DETAILED DESCRIPTION OF THE PREFERRED EMBODIMENTS

Preferred embodiments according to the present invention will be below in detail with reference to the accompanying drawings.

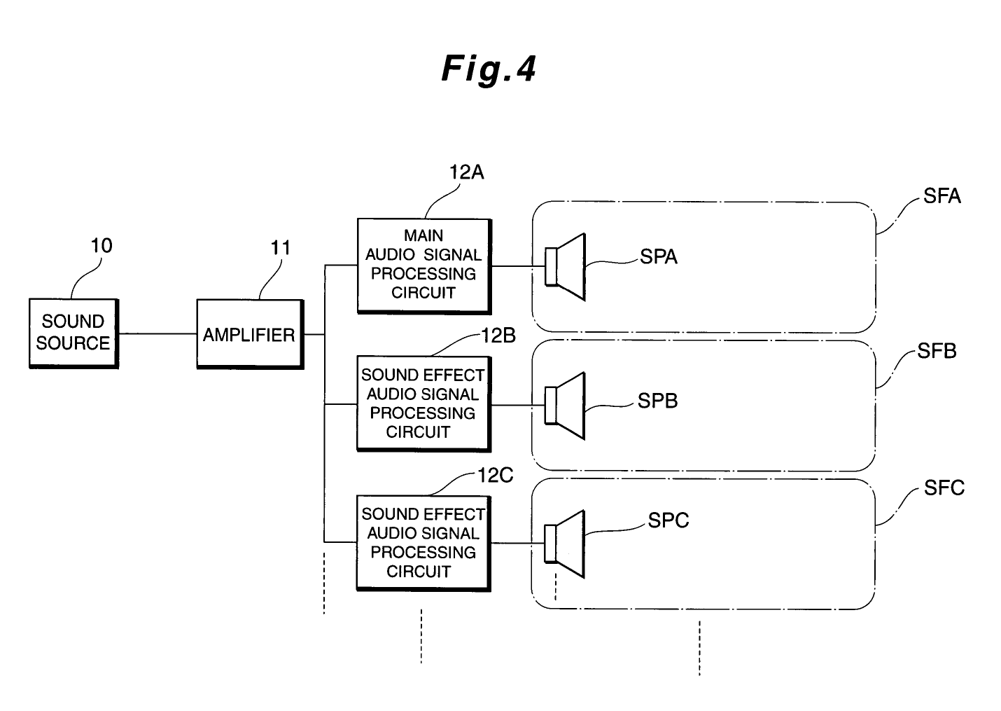

FIG. 4 is a block diagram illustrating a first embodiment of an audio apparatus according to the present invention.

The audio apparatus illustrated in FIG. 4 includes: a main speaker SPA for mainly reproducing source sound; a given number of sound effect speakers (speakers for creating sound effects) SPB, SPC, etc. for reproducing sound effects as will be described later; an amplifier 11 for amplifying an audio signal read from a sound source 10; a main audio signal processing circuit 12A assigned to the main speaker SPA and performing signal processing on the audio signal amplified by the amplifier 11 for reproduction of the source sound; and sound effect audio signal processing circuits 12B, 12C, etc. respectively assigned to the sound effect speakers SPB, SPC, etc. and performing signal processing suitable for the individual sound effect speakers SPB, SPC, etc. on the audio signal amplified by the amplifier 11.

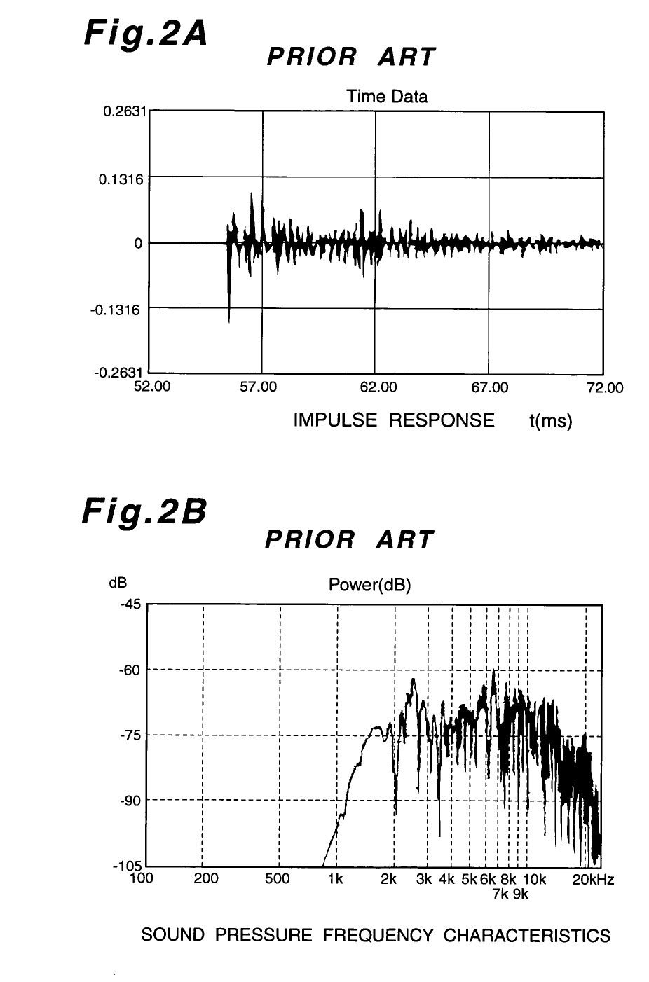

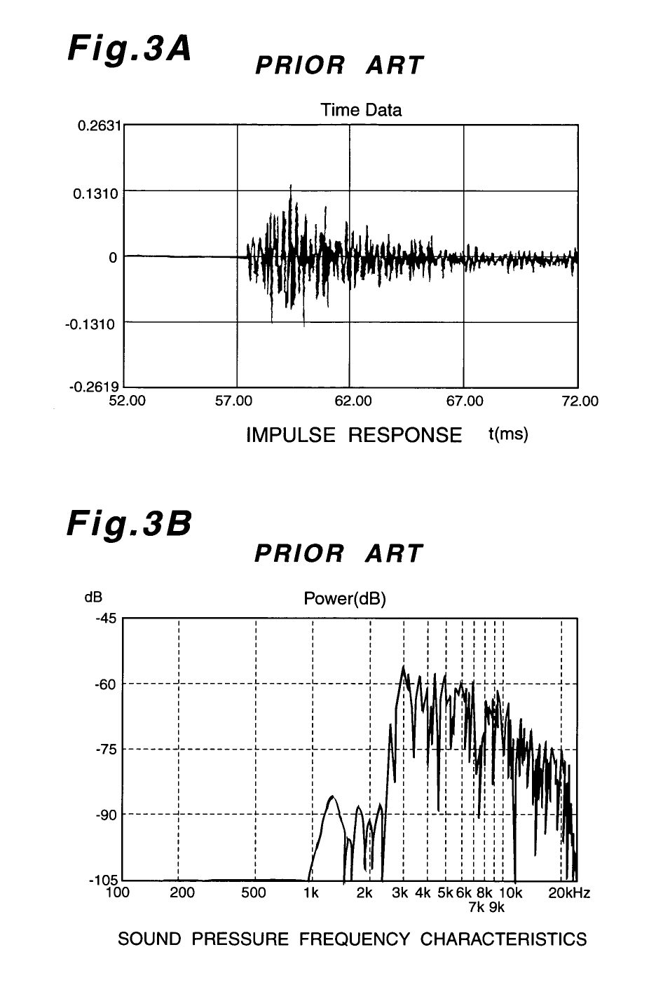

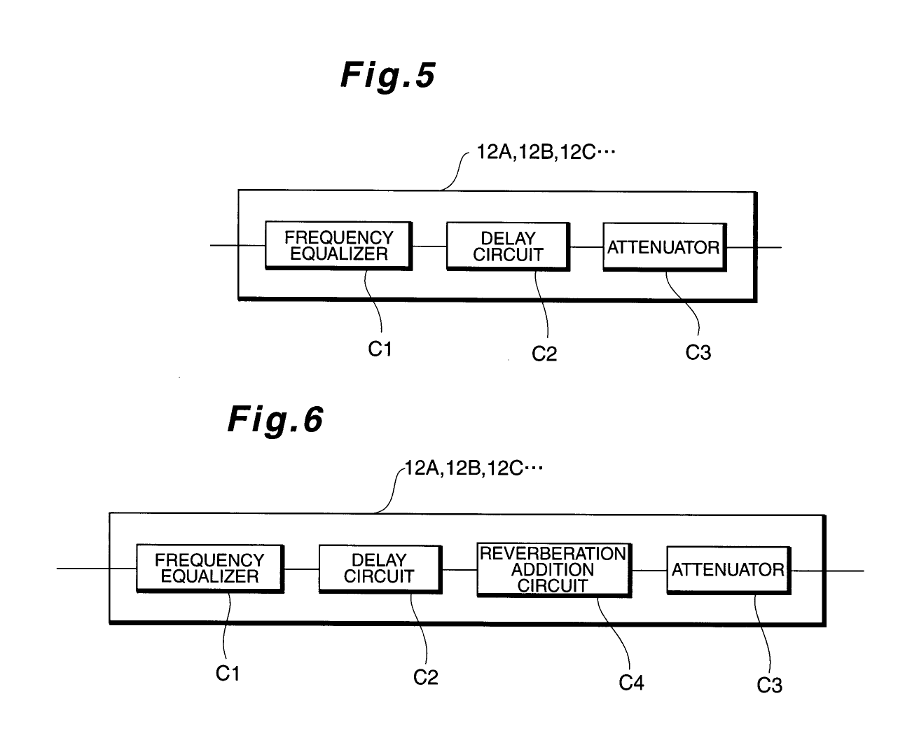

As shown in FIG. 5, each of the signal processing circuits 12A, 12B, 12C, etc. is configured of: a frequency equalizer C1 for correcting the reflection characteristics of a sound-reproduction space in the impulse response (see FIGS. 2A and 3A) and the peak-and-dip characteristics in the frequency characteristics (see FIGS. 2B and 3B), and the like; a delay circuit C2 for adjusting phase of a sound wave to be reproduced from each speaker; and an attenuator C3.

Further, each of the signal processing circuits 12A, 12B, 12C, etc. includes a high-pass filter provided for a tweeter for reproducing high frequency sound and a low-pass filter provided for a woofer for reproducing low frequency sound, which are not shown in the drawings.

In addition to the structure illustrated in FIG. 5, each of the signal processing circuits 12A, 12B, 12C, etc. may include a reverberation addition circuit C4 as illustrated in FIG. 6.

The audio apparatus reads an audio signal from the sound source 10 such as a CD, then amplifies the audio signal in the amplifier 11, and then inputs the amplified audio signal to the main audio signal processing circuit 12A to perform the signal processing required for faithfully reproducing the sound source on the audio signal.

Then, the audio apparatus inputs the audio signal, undergoing the signal processing by the main audio signal processing circuit 12A, to the main speaker SPA, and then outputs the source sound from the main speaker SPA into a sound-reproduction space SFA served by the main speaker SPA.

Meanwhile, the audio signal read from the sound source 10 and amplified by the amplifier 11 is inputted to the sound effect audio signal processing circuits 12B, 12C, etc. as well.

Then, each of the sound effect audio signal processing circuits 12B, 12C, etc. performs signal processing, as will be described later, on the audio signal for creation of sound effects in relation to the corresponding one of the sound effect speakers SPB, SPC, etc.. Then, the audio signals individually undergoing the signal processing are inputted to the corresponding sound effect speakers SPB, SPC, etc. and then outputted from the sound effect speakers SPB, SPC, etc. into the respective sound-reproduction spaces SFB, SFC, etc..

Specifically, the delay circuit C2 (see FIG. 5 or 6) of each of the sound effect audio signal processing circuits 12B, 12C, etc. performs delay processing on the audio signal such that in a predetermined listening position (a position in which a listener hears a reproduced sound), an arrival time of the sound effects outputted from each of the sound effect speakers SPB, SPC, etc. is delayed by a fixed time interval with respect to an arrival time of the source sound outputted from the main speaker SPA.

Further, the attenuator C3 (see FIG. 5 or 6) of each of the sound effect audio signal processing circuits 12B, 12C, etc. performs attenuation processing on the audio signal such that in the listening position, a time waveform within a predetermined time interval from a rise time of the sound effect arriving from the corresponding one of the sound effect speakers SPB, SPC, etc. becomes less than or equal to a value (dB) established with respect to a time waveform within a predetermined time interval from a rise time of the source sound arriving from the main speaker SPA.

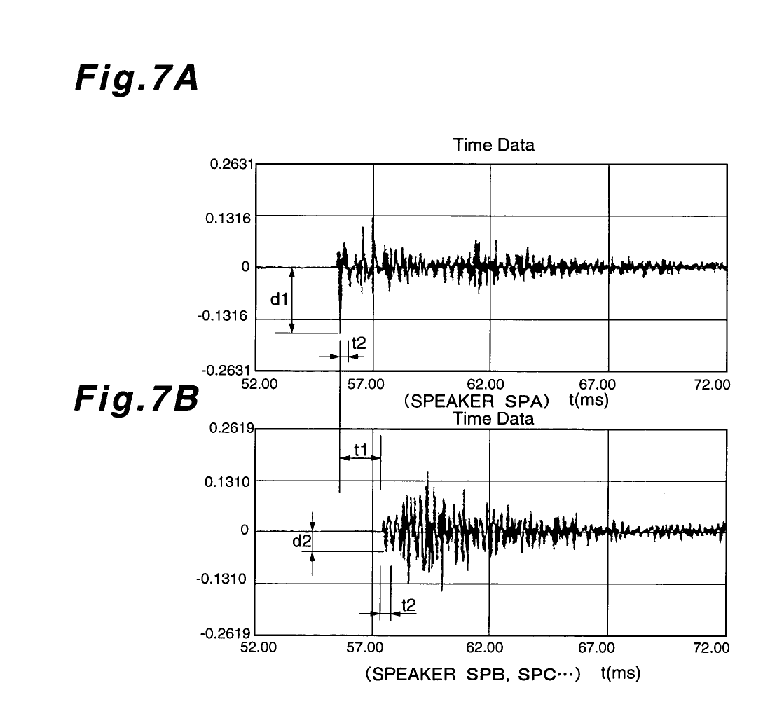

FIG. 7A is a graph illustrating an example of impulse response at output of the main speaker SPA for reproducing the source sound from the audio signal subjected to the signal processing in the main audio signal processing circuit 12A. FIG. 7B is a graph illustrating an example of impulse response at output of each of the sound effect speakers SPB, SPC, etc. for reproducing the sound effects from the audio signal subjected to the signal processing in the corresponding one of the sound effect audio signal processing circuits 12B, 12C, etc.

Comparing FIG. 7A and FIG. 7B, the sound effect outputted from each of the sound effect speakers SPB, SPC, etc. reaches the listening position with a time delay of interval t1 (2 ms in the example illustrated in FIG. 7B) from the arrival time of the source sound outputted from the main speaker SPA.

A difference (d1-d2) between a time waveform d1 (dB) within a predetermined time interval t2 (0.4 ms in the example illustrated in FIG. 7A) from the rise time of the source sound from the main speaker SPA in the listening position, and the time waveform d2 (dB) within a predetermined time interval t2 (0.4 ms in the example illustrated in FIG. 7B) from the rise time of the sound effect outputted from each of the sound effect speakers SPB, SPC, etc. in the listening position is equal to or higher than a predetermined value (e.g. 10 dB).

As described hitherto, the audio apparatus has the main speaker SPA for outputting a source sound and the sound effect speakers SPB, SPC, etc. for outputting sound effects. Then, the source sound undergoing the signal processing in the main speaker audio signal processing circuit 12A is outputted from the main speaker SPA toward the inside the sound-reproduction space SFA (see FIG. 4). Meanwhile, the sound effects created by the audio signals undergoing the signal processing in the individual sound effect audio signal processing circuits 12B, 12C, etc. are outputted from the individual sound effect speakers SPB, SPC, etc. toward the insides of the respective sound-reproduction spaces SFB, SFC, etc.. Hence, as compared with conventional audio apparatuses outputting both source sound and sound effects (pseudo-acoustic sound) into a single sound-reproduction space, the audio apparatus according to the present invention is decreased in the degree of interrelationship between the source sound and the sound effects. This decrease allows the sound effects outputted from the sound effect speakers SPB, SPC, etc. to make it possible for a listener(s) to listen to sound closely analogous to the acoustic of live sound created in a concert hall or the like.

The audio apparatus sets any given values for the delay time t1 and the attenuation rate (see FIGS. 7) of the sound effect with respect to the source sound to be able to offer a high degree of localization for the sound to be reproduced.

For example, when the audio apparatus is used as a vehicle-mounted audio apparatus, a listening position is fixed, such as a driver seat or a front passenger seat. Further the shape of the passenger chamber is predetermined depending on vehicle model. Accordingly, by presetting a delay time t1 and the attenuation rate of sound effects in each of the sound effect audio signal processing circuits 12B, 12C, etc. in accordance with a listening position, such as a driver seat or a front passenger seat, and the capacity/volume and shape of the passenger chamber, a listener such as a driver is able to listen to sound with balanced tone.

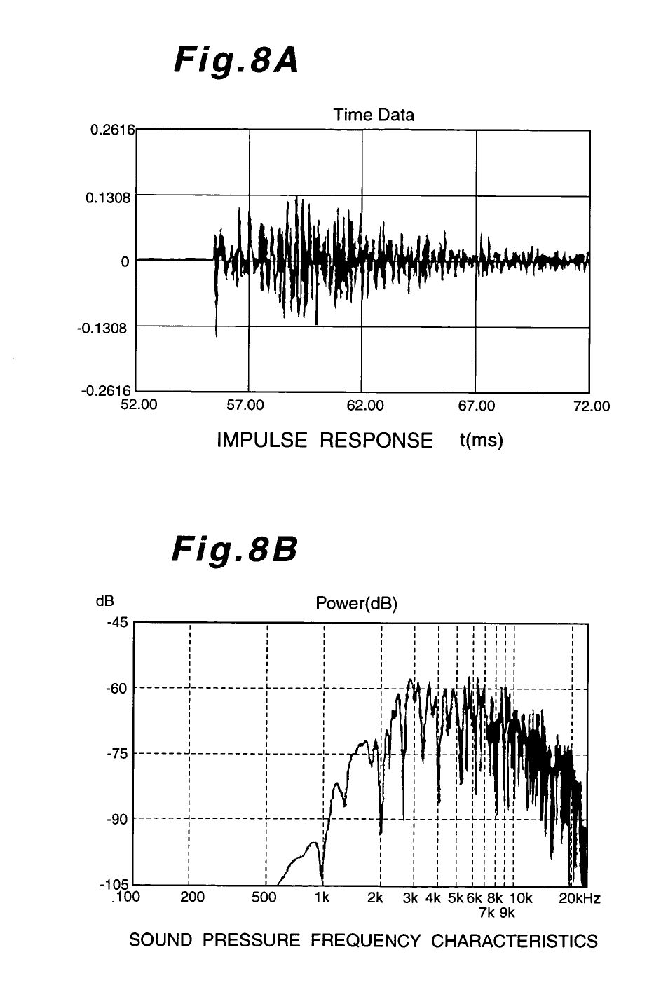

FIGS. 8A and 8B are graphs respectively showing impulse response and sound pressure frequency characteristics when the aforementioned audio apparatus is installed in the passenger chamber of the vehicle and the main speaker SPA and the sound effect speaker SPB, SPC, etc. are mounted to the A-pillar inside the passenger chamber and to a lower portion of a console.

It is understood from FIGS. 8A and 8B that when the aforementioned audio apparatus is used as a vehicle-mounted audio apparatus, a level of the source sound in the impulse response is high and also the sound pressure frequency characteristics are smooth.

In the aforementioned audio speaker, in order to make the sound-reproduction space of each of the sound effect speakers SPB, SPC, etc. different from that of the main speaker SPA, speakers having directivities differing from each other may be preferably used individually for the main speaker SPA and the sound effect speakers SPB, SPC, etc..

Further, in the aforementioned audio apparatus, when each of the main audio signal processing circuit 12A and sound effect audio signal processing circuits 12B, 12C, etc. has the structure illustrated in FIG. 6, the reverberation addition circuit C4 performs the reverberation additional processing on the audio signal, thereby making it possible to reproduce sound further resembling live sound in the concert hall or the like.

The foregoing describes the use of the plurality of sound effect speakers SPB, SPC, etc., but the number of sound effect speakers may be one; e.g. the sound effect speaker SPB.

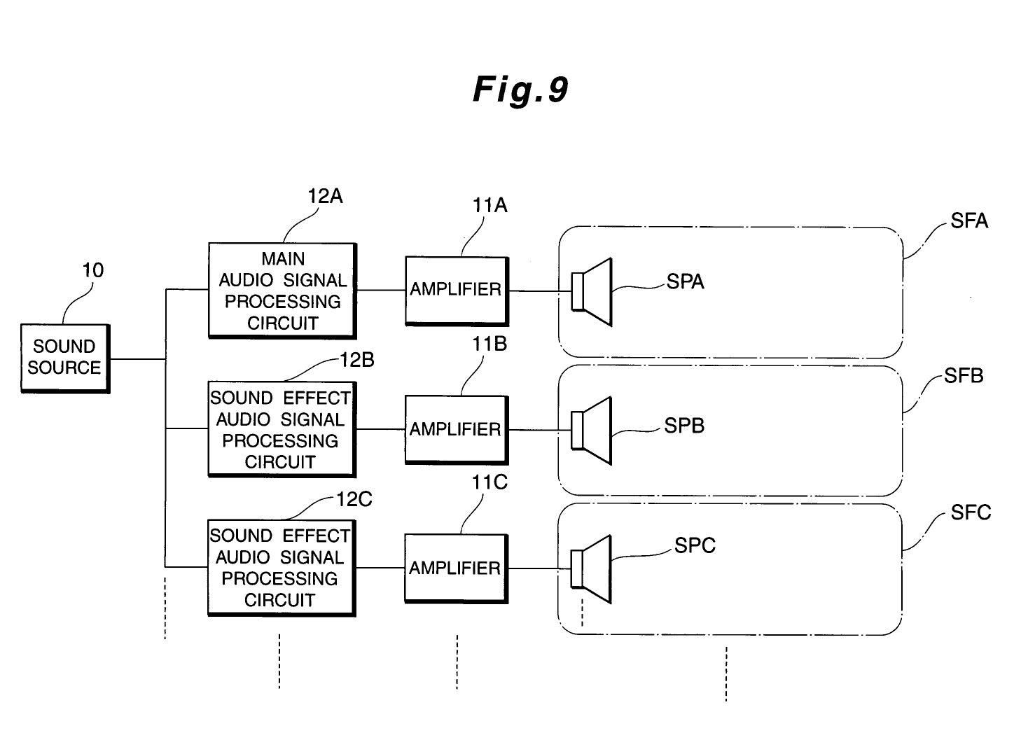

FIG. 9 is a block diagram illustrating a second embodiment of the audio apparatus according to the present invention.

The audio apparatus in the first embodiment described in FIG. 4 is designed such that an audio signal read from the sound source is amplified by the single amplifier, then distributed among the main audio signal processing circuit and the sound effect audio signal processing circuits, and then subjected to the signal processing in each signal processing circuit. In the audio apparatus in FIG. 9, however, the main audio signal processing circuit 12A and the sound effect audio signal processing circuits 12B, 12C, etc. are individually connected to respective amplifiers 11A, 11B, 11C, etc.. Therefore, an audio signal read from the sound source 10 is distributed among the main audio signal processing circuit 12A and the sound effect audio signal circuits 12B, 12C, etc.. Then, the audio signals individually subjected to the signal processing are respectively amplified by the amplifiers 11A, 11B, 11C, etc., and then inputted to the main speaker SPA and the sound effect speakers SPB, SPC, etc..

The audio apparatus according to the second embodiment is capable of reproducing sound with balanced timbre and precise localization as in the case of the first embodiment.

Each of the main audio signal processing circuit 12A and sound effect audio signal processing circuits 12B, 12C, etc. has the structure as illustrated in FIG. 5 or 6 as in the case of the audio apparatus of the first embodiment.

The audio apparatuses in each of the foregoing embodiments is embodied on the basis of a comprehensively general idea in which: an audio apparatus includes a main speaker receiving an audio signal from a sound source and outputting sound of the sound source, a signal processing circuit for performing signal processing on the audio signal sent from the sound source to generate a sound effect audio signal for creation of a sound effect required of the sound of the sound source, and at least one sound effect speaker receiving the sound effect audio signal generated by the signal processing circuit and outputting the sound effect required of the sound of the sound source.

The audio apparatus based on the comprehensively general idea reads an audio signal from the sound source such as a CD, then performs the required signal processing on the audio signal for reproduction of the source sound, and then inputs the resulting audio signal to the main speaker. Thus, the source sound is outputted from the main speaker toward the inside of the sound-reproduction space served by the main speaker.

Further, the audio signal read from the sound source is also inputted to the signal processing circuit. Then, the signal processing circuit performs the signal processing on the audio signal to produce an audio signal for reproducing sound offering the acoustic effect required of the source sound outputted from the main speaker.

Then, the audio signal for reproducing the sound effect after completion of the signal processing in the signal processing circuit is inputted to at least one sound effect speaker, and therefore the sound effect is outputted from the sound effect speaker into the sound-reproduction space.

As described above, the audio apparatus includes a main speaker for outputting a source sound and a sound effect speaker for outputting a sound effect. The source sound is outputted from the main speaker toward the inside of the sound-reproduction space served by the main speaker concerned. The sound effect reproduced from the sound effect audio signal subjected to the signal processing by the signal processing circuit is outputted from the sound effect speaker toward the inside of the sound-reproduction space served by the sound effect speaker concerned.

Hence, as compared with the conventional audio apparatuses in which a source sound and a sound effect (pseudo-acoustic sound) are outputted together into a single sound-reproduction space, the audio apparatus according to the present invention is decreased in the degree of interrelationship between the source sound and the sound effect. As a result, the sound effect outputted from the sound effect speaker makes it possible for a listener(s) to listen to sound analogous to the original acoustic sound in the concert hall or the like.

The audio apparatus is capable of providing precise localization of the sound reproduced. For example, when the audio apparatus is used as a vehicle-mounted audio apparatus, a listener(s) such as the driver of the vehicle is able to hear sound with balanced tone quality.

The terms and description used herein are set forth by way of illustration only and are not meant as limitations. Those skilled in the art will recognize that numerous variations are possible within the spirit and scope of the invention as defined in the following claims.

What is claimed is:

1. An audio apparatus comprising:
a main speaker receiving an audio signal from a sound source and outputting sound of the sound source;
a signal processing circuit for performing signal processing on the audio signal from the sound source to generate a sound effect audio signal for reproduction of a sound effect required of the sound of the sound source; and
at least one sound effect speaker receiving the sound effect audio signal generated by the signal processing circuit and outputting the sound effect required of the sound of the sound source.

2. An audio apparatus according to claim 1, wherein the signal processing circuit includes a frequency equalizer, a delay circuit, and an attenuator.

3. An audio apparatus according to claim 2, wherein the signal processing circuit further includes a reverberation addition circuit.

4. An audio apparatus according to claim 1, wherein the signal processing circuit performs delay processing on the audio signal sent from the sound source to delay a time at which the sound effect outputted from the sound effect speaker arrives at a position of a listener, hearing the sound of the sound source outputted from the main speaker and the sound effect outputted from the sound effect speaker, by a required set-time interval with respect to a time of arrival of the sound of the sound source outputted from the main speaker.

5. An audio apparatus according to claim 1, wherein the signal processing circuit performs attenuation processing on the audio signal sent from the sound source to decrease a sound pressure level within a required set-time interval starting from a rise time of the sound effect outputted from the sound effect speaker in a position of a listener hearing the sound of the sound source outputted from the main speaker and the sound effect outputted from the sound effect speaker, to a required set value smaller than a sound pressure level within the predetermined set-time interval starting from a rise time of the sound of the source sound outputted from the main speaker.

6. An audio apparatus according to claim 1, wherein the audio apparatus is a vehicle-mounted audio apparatus using a passenger chamber of a vehicle as a sound-reproduction space for the main speaker and the sound effect speaker.
